(19) United States
(12) Patent Application Publication
(10) Pub. No.: US 2015/0194559 A1
(43) Pub. Date: Jul. 9, 2015

(54) PHOTOVOLTAIC MODULE WITH SOLAR CONCENTRATION

(71) Applicant: SHUNSIN TECHNOLOGY (ZHONG SHAN) LIMITED, Zhongshan (CN)

(72) Inventor: FEI REN, Zhongshan (CN)

(21) Appl. No.: 14/524,692

(22) Filed: Oct. 27, 2014

(30) Foreign Application Priority Data
Jan. 9, 2014 (CN) 201410009913.X

(51) Int. Cl. H01L 31/054

(52) U.S. Cl. CPC H01L 31/0543; H01L 31/0547

(57) ABSTRACT

A light-concentrating photovoltaic module includes a substrate having a circuit, an array of solar cells located on the substrate and an optical element for focusing light onto the solar cells. The optical element is electrically connected to the circuit. Each of the solar cells has a first conductive region and a second conductive region, the first conductive region is electrically connected to the circuit, the second conductive region is electrically connected to the optical element to interconnect all the solar cells within the array of solar cells.

### FIELD

The present disclosure relates to photovoltaic systems, and more particularly to a photovoltaic module with light concentration.

### BACKGROUND

Photovoltaic modules may concentrate sunlight onto photovoltaic surfaces to generate electrical energy. Such a photovoltaic module uses a number of solar cells to turn the sunlight into electrical energy, and use a primary optical element to focus light onto the solar cells. The solar cells are electrically interconnected by gold wires, which utilizes a large amount of gold.

### BRIEF DESCRIPTION OF THE DRAWINGS

Implementations of the present technology will now be described, by way of example only, with reference to the attached figures.

FIG. 1 is a cross-sectional view of a light-concentrating photovoltaic module in accordance with an embodiment of the present disclosure.

FIG. 2 is an enlarged view of the circled portion II of FIG. 1.

FIG. 3 is an enlarged view of the circled portion III of FIG. 2.

FIG. 4 is another embodiment of the device shown in FIG. 3.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape or other word that substantially modifies, such that the component need not be exact. For example, substantially cylindrical means that the object resembles a cylinder, but can have one or more deviations from a true cylinder.

The following disclosure is described in relation to a light-concentrating photovoltaic module 100.

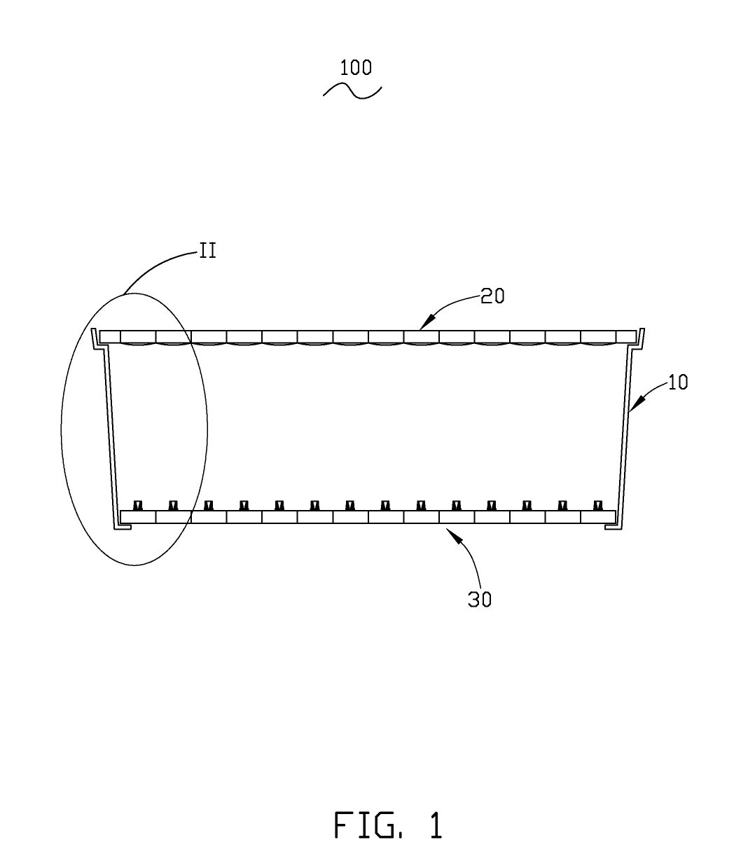

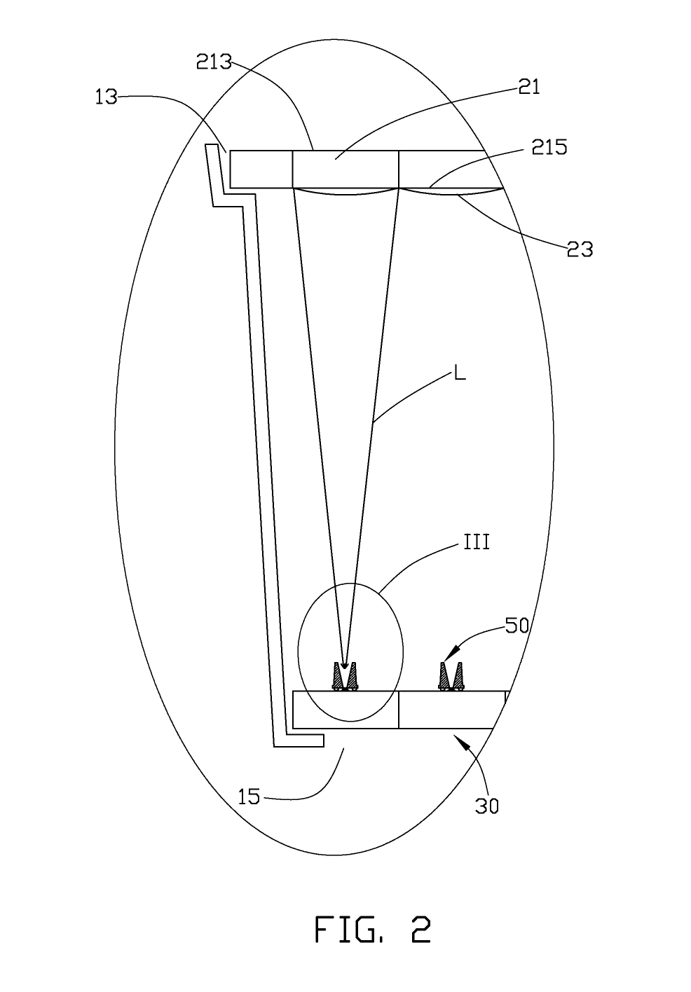

FIG. 1 and FIG. 2 illustrate a light-concentrating photovoltaic module 100. The light-concentrating photovoltaic module 100 includes a substrate 30, an array of solar cells 40, a plurality of secondary optical elements 50, a primary optical element 20, and an outer frame 10. The outer frame 10 defines a first opening 13 and a second opening 15. The substrate 30 is located on the second opening 15. The primary optical element 20 is located on the first opening 13. The primary optical element 20 is above the substrate 30. The solar cells 40 are mounted on a top surface of the substrate 30. The secondary optical elements 50 are located on the top surface of the substrate 30 and correspond to the solar cells 40. The primary optical element 20 focuses light into the outer frame 10. The secondary optical element 50 provides a secondary focus of the light focused by the primary optical element 20, and electrically connects the solar cells 40 and the substrate 30. The solar cells 40 convert light energy into electrical energy.

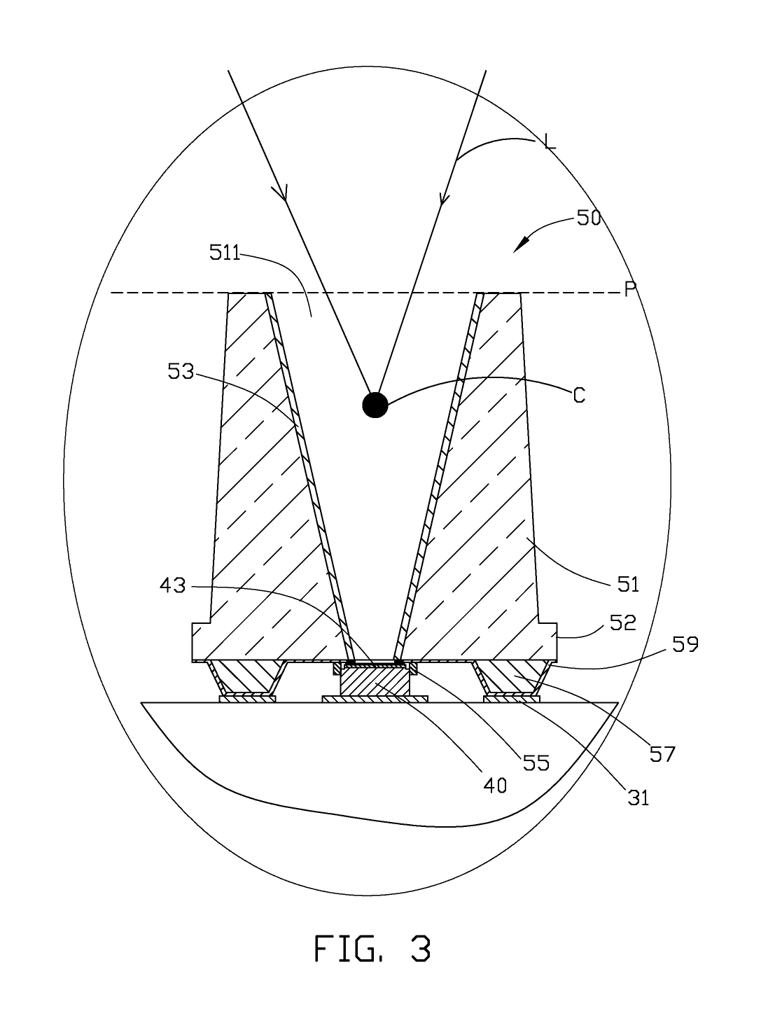

FIG. 3 illustrates the substrate 30 further includes a circuit 31 made of conductive material. In the embodiment, the circuit 31 is made of printed conductive ink, and the solar cells 40 and the secondary optical elements 50 are bonded to the substrate 30 via the printed conductive ink, the conductive ink is then solidified to fix the solar cells 40 and the secondary optical elements 50 on the substrate 30. Therefore, the solar cells 40 and the secondary optical elements 50 are fixed on the substrate 30 without copper or other expensive metal to improve the cost efficiency of the module 100. In other embodiments, the solar cells 40 and the secondary optical elements 50 are mounted on the substrate 30 by conductive adhesive or by soldering.

The solar cells 40 are electrically mounted on the circuit 31. The solar cells 40 are electrically connected with each other by the circuit 31. The solar cell 40 has a top surface facing the secondary optical element 50, and a bottom surface facing the substrate. Each of solar cells 40 includes a light receiving surface 43, a first conductive region 42 and second conductive region 41. The solar cell 40 may be a multi junction solar cell 40 containing semiconductor layers, and the first and the second conductive regions 41, 42 may be semiconductor regions of opposite conductivity types (e.g., N-type and P-type). In the embodiment, the light receiving surface 43 is arranged on the top surface; the first and the second conductive regions 41, 42 are formed on the top and the bottom surface of the solar cell 40 respectively.

The secondary optical element 50 includes a secondary optical body 51, which is made of polymer material and substantially cuboid. The secondary optical body 51 defines a light hole 511 for allowing light to pass through to the light receiving surface 43. The secondary optical body 51 has a sloped sidewall 513 forming the light hole 511. The sloped sidewall 513 is coated with a reflective layer 53, the reflective layer 53 reflects light received from the primary optical element 20. The reflective layer 53 reduces solar energy losses. A diameter of the light hole 511 gradually decreases from a top end of the light hole 511 adjacent to the primary optical element 20 towards a bottom end of the light hole 511 adjacent to the solar cells 40, and a central vertical line of the top opening 5111 aligns with a central vertical line of the bottom opening 5113. In other embodiments, the shape of the top end 5111 and the bottom end 5113 may be square, hexagonal or octagonal.

A plurality of support protrusions 57 are arranged on corners of bottom surface 515. The support protrusions 57 support the secondary optical element 50 on the substrate 30. Each of the support protrusions 57 protrudes downwardly from the bottom surface 515, a bottom surface of the support protrusion 57 is square, and the area of the bottom surface gradually decreases in a direction away from the bottom surface 515. In other embodiments, the bottom surface of the support protrusion 57 may be round or triangular. The structure of the support protrusion 57 described gives some strength to the support protrusion 57 preventing fractures due to mishandling during assembly.

A conductive film 59 is provided on the secondary optical element 50. The conductive film 59 is coated on the bottom surface 515 and outer surfaces of the support protrusions 57. In assembly, the solar cell 40 is mounted on the bottom surface 515 with the light receiving surface 43 aligned to light hole 511, the first conductive region 42 electrically connects to the conductive film 59. When the secondary optical element 50 is supported on the substrate 30, the conductive film 59 coated on the bottom surface of the support protrusion 57 electrically connects to the circuit 31, so the first conductive region 42 is electrically connected to the circuit 31. At the same time, the second conductive region 41 electrically connects to the circuit 31 directly. Because the solar cell 40 is directly bonded to the secondary optical body 51 with no gap, the structure reduces losses from light leakage, and improves light conversion performance.

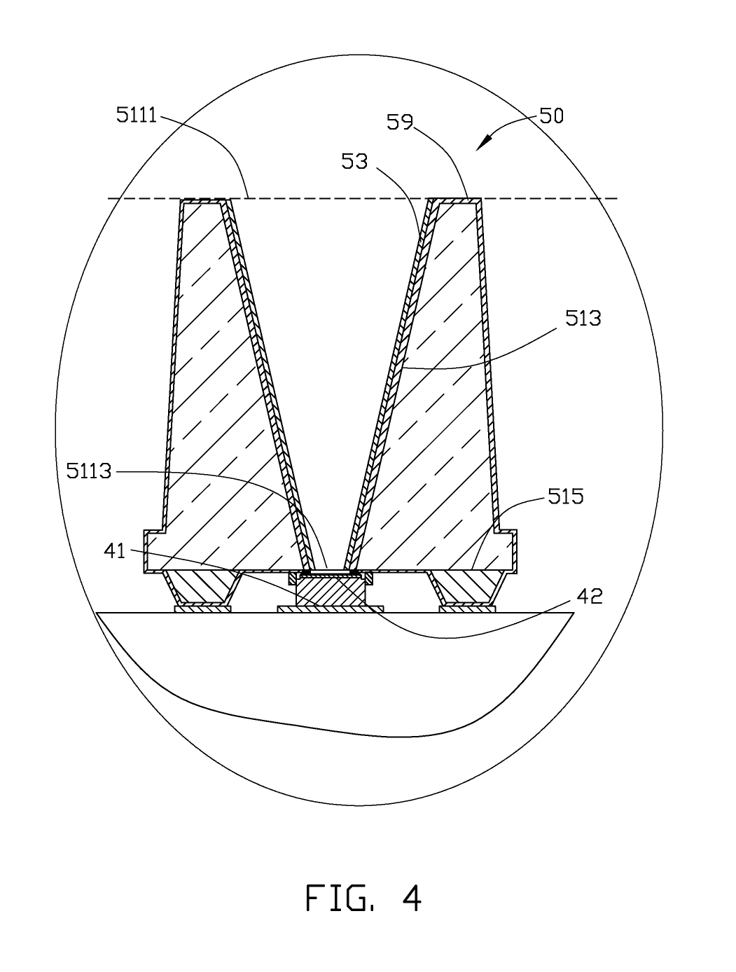

FIG. 4 illustrates, in other embodiments, the conductive film 59 is coated on an entire outer surface of the secondary optical body 51, the sloped sidewall 513, and outer surfaces of the support protrusions 57. The reflective layer 53 is coated on the conductive film 59 within the light hole 511. The structure just described allows the secondary optical element 50 to be applied to high temperature environments.

A plurality of limiting protrusions 55 are arranged around the bottom end 5113. The limiting protrusions 55 cooperatively define an assembling space for limiting a location of the solar cell 40, which improves the precise alignment between the light hole 511 and the light receiving surface 43. A ring-shaped protrusion 52 protrudes outwardly from an outer periphery of the secondary optical body 51, and the ring-shaped protrusion 52 is adjacent to the bottom surface 515. With the ring-shaped protrusion 52 in place, the secondary optical body 51 can be easily mounted on the substrate 30.

The primary optical element 20 comprises a glass plate 21. A bottom surface 215 of the glass plate 21 opposite to the substrate 30 is arranged with an array of lenses 23. In the embodiment, the lenses 23 connect with each other. In other embodiments, the lenses 23 are spaced from each other. Each of the lenses 23 can concentrate the light received from the glass plate 21 and form the light beam L, and then the secondary optical element 50 focuses the light beam L onto the light receiving surfaces 43. The array of lenses 23 faces the array of solar cells 40, with each focus C of the lenses 23 aligned to each center of a solar cell 40.

In assembly, the array of solar cells 40 is connected to the bottom surface 515, with the second conductive region 41 electrically coupled with the conductive film 59, and the light receiving surface 43 aligned with the light hole 511. The secondary optical bodies 51 are electrically and mechanically coupled with the circuit 31 via the support protrusions 57 and the conductive film 59, with the first conductive region 42 electrically coupled with the circuit 31. The array of solar cells 40 is thus electrically interconnected in serial or parallel via the circuit 31 and the secondary optical element 50 has no wires of gold or other conductive metal thereby improving manufacturing and cost efficiency. The substrate 30 with the array of solar cells 40 and the secondary optical elements 50 is supported on the second opening 15, and the primary optical element 20 is supported on the first opening 13. With the focus C of each lens, the light hole 511 is aligned to the light receiving surface 43. In the embodiment, the focus C is located under a plane P defined by an end of the secondary optical body 51 adjacent to the primary optical element. In other embodiments, the focus C is located upon the plane P defined by an end of the secondary optical body 51 adjacent to the primary optical element.

In use, the light passes through the glass plate 21 and is concentrated by the lens 23 to form light beam L, the light beam L is concentrated and focused onto the light receiving surface 43 of the solar cell 40, aided by the reflection of the reflective layer 53.

Many details are often found in the art such as the other features of a shielding plate. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. A light-concentrating photovoltaic module comprising:
a substrate having a circuit;
an array of solar cells located on the substrate; and
an optical element that focuses light onto the solar cells, the optical element being electrically connected to the circuit;
wherein each of the solar cells has a first conductive region and a second conductive region, the first conductive region is electrically connected to the circuit, the second conductive region is electrically connected to the optical element thereby electrically interconnecting the array of solar cells.

2. The light-concentrating photovoltaic module of claim 1, wherein the optical element comprises a primary optical element and a plurality of secondary optical elements, the primary optical element is separated from the substrate, the secondary optical elements are electrically connected to the circuit and correspond to the solar cells, respectively, and the solar cell is electrically connected to the corresponding secondary optical element.

3. The light-concentrating photovoltaic module of claim 2, wherein each of the secondary optical elements comprises a plurality of support protrusions and a conductive film, the support protrusions support the secondary optical element on the substrate, and the conductive film electrically connects the second conductive region to the circuit.

4. The light-concentrating photovoltaic module of claim 2, wherein the secondary optical element has a secondary optical body, the secondary optical body defines a light hole for concentrating light onto the solar cell, the solar cell is mounted on a bottom surface of the secondary optical body facing to the substrate with a center of the light hole substantially aligning with a center of the solar cell.

5. The light-concentrating photovoltaic module of claim 4, wherein the conductive film is coated on outer surfaces of the support protrusions and the bottom surface, and the support protrusions provide support on the substrate, and the conductive film electrically connects the second conductive region to the circuit.

6. The light-concentrating photovoltaic module of claim 4, wherein the support protrusions are arranged on the bottom surface around the solar cell.

7. The light-concentrating photovoltaic module of claim 4, wherein the bottom surface is arranged with a plurality of limiting protrusions that cooperatively hold the solar cell.

8. The light-concentrating photovoltaic module of claim 4, wherein a protrusion protrudes outwardly from an outer periphery of the secondary optical body, and the protrusion is adjacent to the bottom surface of the secondary optical body.

9. The light-concentrating photovoltaic module of claim 4, wherein a diameter of the light hole gradually decreases from a top end of the light hole adjacent to the primary optical element to a bottom end of the light hole adjacent to the solar cell.

10. The light-concentrating photovoltaic module of claim 4, wherein the secondary optical body has a sloped sidewall surrounding the light hole, and the sloped sidewall is coated with a reflective layer to concentrate light received from the primary optical element onto the solar cell.

11. The light-concentrating photovoltaic module of claim 10, wherein the conductive film is coated on an outer surface of the secondary optical body, the sloped sidewall and outer surfaces of the support protrusions.

12. The light-concentrating photovoltaic module of claim 11, wherein a reflective layer is coated on the conductive film arranged on the sloped sidewall that concentrates light received from the primary optical element onto the solar cell.

13. The light-concentrating photovoltaic module of claim 1, wherein the primary optical element comprises a glass plate, an array of lenses are arranged on the glass plate and respectively face the solar cells, each focus of the lenses align to each center of the corresponding solar cell.

14. The light-concentrating photovoltaic module of claim 13, wherein the focus of the lens locates under a plane defined by an end of the secondary optical body adjacent to the primary optical element.

15. The light-concentrating photovoltaic module of claim 13, wherein the focus of the lens locates on a plane defined by an end of the secondary optical body adjacent to the primary optical element.

16. A light-concentrating photovoltaic module comprising:
a substrate having a circuit;
an array of solar cells located on the substrate; and
an optical element for focusing light onto the solar cells, the optical element electrically connects each of the solar cells to the circuit thereby electrically interconnecting the solar cells.

17. The light-concentrating photovoltaic module of claim 16, wherein the optical element comprises a primary optical element and a plurality of secondary optical elements corresponding to the solar cells respectively, the primary optical element is separated from the substrate, each secondary optical element electrically connects the corresponding solar cell and the circuit for electrically interconnecting the solar cells with each other.

18. The light-concentrating photovoltaic module of claim 17, wherein each of the secondary optical elements has a plurality of support protrusions and a conductive film, the support protrusions support the secondary optical elements on the substrate, and the conductive film electrically interconnects the solar cell to the circuit.

19. The light-concentrating photovoltaic module of claim 17, wherein the secondary optical element has a secondary optical body, the secondary optical body defines a light hole for concentrating light onto the solar cell, the solar cell is mounted on a bottom surface of the secondary optical body facing toward the substrate with a center of the light hole substantially aligning with a center of the solar cell.

20. The light-concentrating photovoltaic module of claim 19, wherein the conductive film is coated on the bottom surface of the secondary optical body and the outer surfaces of the support protrusions.
